(19) United States
(12) Patent Application Publication
(10) Pub. No.: US 2011/0115018 A1
(43) Pub. Date: May 19, 2011

(54) MOS POWER TRANSISTOR

(75) Inventor: Joel Montgomery McGregor, Nelson (CA)

(73) Assignee: MAXIM INTEGRATED PRODUCTS, INC., Sunnyvale, CA (US)

(21) Appl. No.: 12/618,515

(22) Filed: Nov. 13, 2009

(51) Int. Cl. H01L 29/78; H01L 21/336

(52) U.S. Cl. 257/341; 438/286; 257/343; 257/E21.417; 257/E29.256

(57) ABSTRACT

A split gate power transistor includes a laterally configured power MOSFET including a doped silicon substrate, a gate oxide layer formed on a surface of the substrate, and a split polysilicon layer formed over the gate oxide layer. The polysilicon layer is cut into two electrically isolated portions, a first portion forming a polysilicon gate positioned over a channel region of the substrate, and a second portion forming a polysilicon field plate formed over a portion of a transition region of the substrate. The field plate also extends over a drift region of the substrate, where the drift region is under a field oxide filled trench formed in the substrate. The field plate is electrically coupled to a source of the split gate power transistor.

### FIELD OF THE INVENTION

The present invention relates to the field of power transistors. More particularly, the present invention relates to the field of integrated MOS power transistors with reduced gate charge.

### BACKGROUND OF THE INVENTION

A power supply is a device or system that supplies electrical or other types of energy to an output load or group of loads. The term power supply can refer to a main power distribution system and other primary or secondary sources of energy. A switched-mode power supply, switching-mode power supply or SMPS, is a power supply that incorporates a switching regulator. While a linear regulator uses a transistor biased in its active region to specify an output voltage, a SMPS actively switches a transistor between full saturation and full cutoff at a high rate. The resulting rectangular waveform is then passed through a low-pass filter, typically an inductor and capacitor (LC) circuit, to achieve an approximated output voltage.

A MOSFET (Metal-Oxide-Semiconductor Field-Effect Transistor) is commonly used in SMPSs. A MOSFET has a gate, a drain, and a source terminal, as well as a fourth terminal called the body, base, bulk, or substrate. The substrate simply refers to the bulk of the semiconductor in which the gate, source, and drain lie. The fourth terminal functions to bias the transistor into operation. The gate terminal regulates electron flow through a channel region in the substrate, either enabling or blocking electron flow through the channel. Electrons flow through the channel from the source terminal towards the drain terminal when influenced by an applied voltage.

The channel of a MOSFET is doped to produce either an N-type semiconductor or a P-type semiconductor. The drain and source may be doped of opposite type to the channel, in the case of enhancement mode MOSFETs, or doped of similar type to the channel as in depletion mode MOSFETs. The MOSFET utilizes an insulator, such as silicon dioxide, between the gate and the substrate. This insulator is commonly referred to as the gate oxide. As such, the gate terminal is separated from the channel in the substrate by the gate oxide.

When a voltage is applied between the gate and source terminals, the electric field generated penetrates through the gate oxide and creates a so-called “inversion layer”, or channel, at the semiconductor-insulator interface. The inversion channel is of the same type, P-type or N-type, as the source and drain, so as to provide a channel through which current can pass. Varying the voltage between the gate and substrate modulates the conductivity of this layer, which functions to control the current flow between drain and source.

A power MOSFET is a specific type of MOSFET widely used as a low-voltage switch, for example less than 200V. A lateral power MOSFET refers to a configuration where both the drain and the source are positioned lateral of each other, such as both at the top surface of the substrate. This is in contrast to a vertical power MOSFET where the drain and source are stacked vertically relative to each other, such as the source at the top surface of the substrate and the drain at the bottom surface.

One limiting factor in how fast the power MOSFET can be switched on and off is the amount of gate charge needed to turn the transistor on and off. The gate charge refers to the number of electrons that are moved into and out of the gate to turn the transistor on and off; respectively. The larger the needed gate charge, the more time to switch the transistor on and off. There is an advantage to quickly switching the power transistor in a switch-mode power supply. The higher the frequency, the smaller the size of the discrete components used in the gate drive circuit of the SMPS. Smaller components are less expensive than larger components.

FIG. 1 illustrates a cut-out side view of an exemplary configuration of a conventional lateral power MOSFET. In this exemplary configuration, the substrate 10 is doped to form a P-type region, or well, 12 and a N-type region, or well, 14. The P-type well 12 includes a double diffused source 16 having a merged contact 24 between a P+ region 20 and a N+ region 22. The contact 24 shorts the P+ region 20 and the N+ region 22 together. The contact 24 functions as a source contact of the power transistor, and the source is shorted to the body of the substrate, which is P-type in this exemplary configuration. A source contact terminal 42 is coupled to the contact 24, and therefore to the source 16. The substrate 10 is also doped to form a N+ region 18 within the N-type region 14. The N+ region 18 functions as the drain of the power transistor. A drain contact terminal 40 is coupled to the drain 18. A trench 26 is formed in a top surface of the substrate 10. The trench 26 is filled with field oxide. The trench 26 can be formed using Shallow Trench Isolation (STI) and in this case the field oxide filled trench is referred to as a shallow trench isolation (STI) region.

A gate oxide 28 is formed on the top surface of the substrate 10. A polysilicon gate 30 is formed over the gate oxide 28. As shown in FIG. 1, the gate oxide layer 28 between the polysilicon gate 30 and the substrate 10 is a thin oxide layer. The polysilicon gate 30 extends over the STI region to support high drain-to-gate voltage.

There are three main regions in the substrate 10 relative to the operation of the power transistor: a channel region, a transition region, and a drift region. The channel region is formed underneath the polysilicon gate 30 and in the P-type region 12 of the substrate 10. In other words, the channel region is formed where the polysilicon gate 30 overlaps the P-type region 12. The drift region is the portion of the N-type region 12 underneath the trench 26, or the STI region. The drift region is where most of the drain-to-gate voltage is dropped in the transistor off state. The STI region is necessary to achieve a high drain-to-gate voltage. If the polysilicon gate 30 were to instead terminate over the thin gate oxide, this would result in too high a voltage across the gate oxide and the power transistor would not function. As such, the STI region and the polysilicon gate extension over the STI region are necessary to drop the high gate-to-drain voltage.

The transition region is the portion of the N-type region 12 underneath the gate oxide 28 and the polysilicon gate 30. The transition region provides a current flow path from the channel region to the drift region when the power transistor is turned on. The transition region is also referred to as the accumulation region or the neck region. In many applications, the transition region accounts for the largest single component of on-resistance in a low-voltage power MOSFET. The length of the transition region is an important design consideration, where the length refers to the horizontal direction in FIG. 1. If the length is too short, the on-resistance of the power MOSFET increases, and the device suffers from early quasi-saturation when turned on hard. If the length is too long, the on-resistance saturates, the specific on-resistance increases, and the breakdown voltage drops. The portion of the polysilicon gate 30 positioned over the transition region accounts for a significant portion of the gate capacitance, and therefore the gate charge.

### SUMMARY OF THE INVENTION

A split gate power transistor includes a laterally configured power MOSFET including a doped silicon substrate, a gate oxide layer formed on a surface of the substrate, and a split polysilicon layer formed over the gate oxide layer. The polysilicon layer is cut into two electrically isolated portions, a first portion forming a polysilicon gate positioned over a channel region of the substrate, and a second portion forming a polysilicon field plate formed over a portion of a transition region of the substrate. The field plate also extends over a drift region of the substrate, where the drift region is under a field oxide filled trench formed in the substrate. The field plate is electrically coupled to a source of the split gate power transistor.

In an aspect, a split gate power transistor is disclosed. The split gate power transistor includes: a doped substrate comprising a source and a channel region within a first doped region, a drain and a transition region within a second doped region, and a trench within the second doped region, wherein the trench is formed in a first surface of the substrate and the trench is filled with field oxide, further wherein the channel region is positioned between the source and the transition region, the transition region is positioned between the channel region and the trench, and the trench is positioned between the transition region and the drain; a gate oxide layer positioned on the first surface of the substrate; a gate positioned on the gate oxide layer and over the channel region; and a field plate positioned on the gate oxide layer and over a first portion of the transition region and a portion of the trench, wherein the gate is separated from the field plate such that a second portion of the transition region is uncovered by both the gate and the field plate, further wherein the field plate is electrically coupled to the drain via a conductive trace.

In another aspect, a method of fabricating a split gate power transistor is disclosed. The method includes: doping a substrate to form a source and a channel region within a first doped region, a drain and a transition region within a second doped region, wherein the channel region is positioned between the source and the transition region, and the transition region is positioned between the channel region and the drain; forming a trench within a portion of the transition region proximate the drain; filling the trench with a field oxide; applying a gate oxide layer to a top surface of the substrate; forming a conductive layer over the channel region, the transition region, and a portion of the trench; removing a portion of the conductive layer over a first portion of the transition region, thereby forming two separate conductive layer portions including a first conductive layer portion positioned over the channel region, and a second conductive layer portion positioned over a second portion of the transition region and the portion of the trench; and forming a conductive trace to electrically couple the second conductive layer portion to the source.

In some embodiments, the gate and the field plate are polysilicon. In some embodiments, the first doped region is a P-type region and the second doped region is a N-type region. In some embodiments, the power transistor comprises a lateral double-diffused metal-oxide-semiconductor field-effect transistor. The doped substrate also includes a drift region within the second doped region, wherein the drift region is positioned under the trench. The power transistor also includes a conductive drain terminal coupled to the drain and a conductive source terminal coupled to the source, wherein the source terminal is coupled to the field plate via the conductive trace. In some embodiments, the substrate comprises a silicon substrate. In some embodiments, the source comprises a double-diffused region. In some embodiments, the trench is formed using a shallow trench isolation process.

### BRIEF DESCRIPTION OF THE DRAWINGS

FIG. 1 illustrates a cut-out side view of an exemplary configuration of a conventional lateral power MOSFET.

FIG. 2 illustrates a cut-out side view of a split gate laterally-configured power transistor according to an embodiment.

FIG. 3 illustrates a gate charge curve for a conventional power MOSFET, such as that shown in FIG. 1, and the split gate power MOSFET of FIG. 2.

Embodiments of the split gate power transistor are described relative to the several views of the drawings. Where appropriate and only where identical elements are disclosed and shown in more than one drawing, the same reference numeral will be used to represent such identical elements.

### DETAILED DESCRIPTION OF THE EMBODIMENTS

Embodiments of the present application are directed to a split gate power transistor. Those of ordinary skill in the art will realize that the following detailed description of the split gate power transistor is illustrative only and is not intended to be in any way limiting. Other embodiments of the split gate power transistor will readily suggest themselves to such skilled persons having the benefit of this disclosure.

Reference will now be made in detail to implementations of the split gate power transistor as illustrated in the accompanying drawings. The same reference indicators will be used throughout the drawings and the following detailed description to refer to the same or like parts.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application and business related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

Embodiments of a split gate power transistor include a laterally configured power MOSFET including a doped silicon substrate, a gate oxide layer formed on a surface of the substrate, and a split polysilicon layer formed over the gate oxide layer. The polysilicon layer is cut into two electrically isolated portions, a first portion forming a polysilicon gate positioned over a channel region of the substrate, and a second portion forming a polysilicon field plate formed over a portion of a transition region of the substrate. The field plate also extends over a drift region of the substrate, where the drift region is under a field oxide filled trench formed in the substrate. The field plate is electrically coupled to a source of the power transistor.

The polysilicon layer is cut over the transition region. As a significant portion of the gate capacitance is due to the portion of the polysilicon gate formed over the transition region, removal of the cut polysilicon over the transition region reduces the gate capacitance, and therefore the gate charge. For a given on-resistance, the split gate configuration reduces the gate charge per cycle by about 50%. The gate charge determines how fast a switch is turned on and off. Reducing the gate charge allows for faster switching, and therefore higher frequency, at the same efficiency for the entire system. The higher frequency allows for the use of smaller discrete components which reduces costs. The split gate power transistor configuration is applicable to all switchable power supply integrated circuits that have internal switches. This configuration is not limited to integrated MOSFETs. The split gate power transistor configuration can be applied to any lateral power MOSFET, either integrated or discrete.

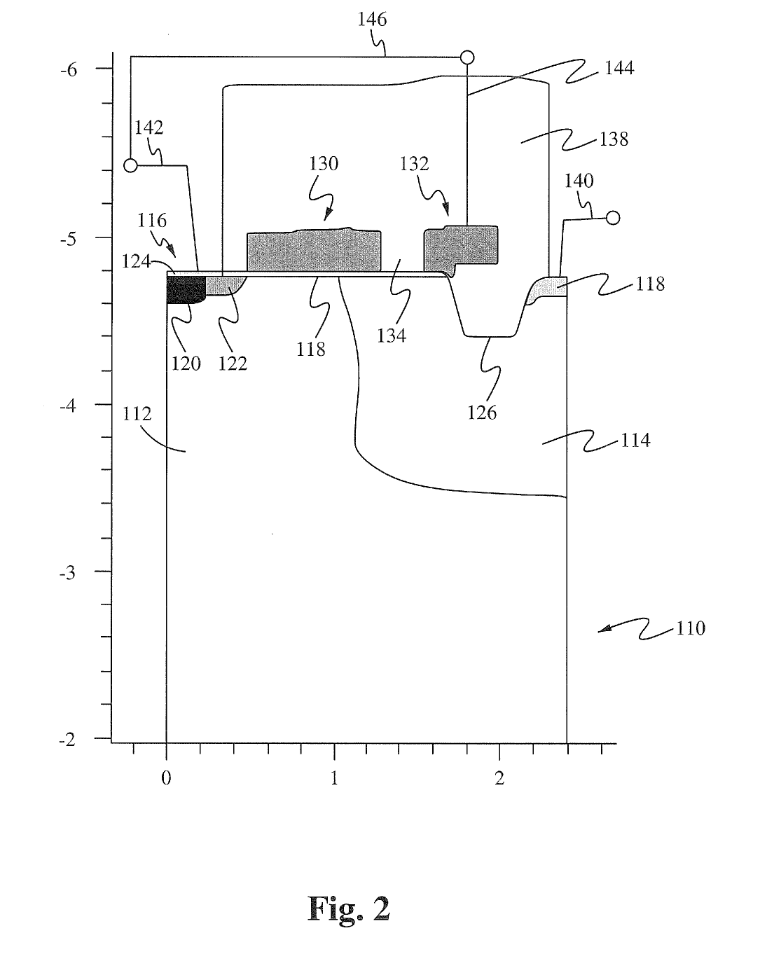

FIG. 2 illustrates a cut-out side view of a split gate laterally-configured power transistor according to an embodiment. In this exemplary configuration, the power transistor is a N-channel double-diffused MOSFET (N-channel DMOSFET). The substrate 110 is doped to form a P-type region 112 and a N-type region 114. The P-type region 112 includes a double-diffused source 116 having a merged contact 124 between a P+ region 120 and a N+ region 122. The contact 124 shorts the P+ region 120 and the N+ region 122 together. The contact 124 functions as a source contact of the split gate power transistor, and the source is shorted to the body of the substrate, which is P-type. The P-type region extends across the entire width of the lower portion of the substrate 110, including underneath the N-type region 114 on the right hand side of FIG. 2. A source contact terminal 142 is coupled to the contact 124, and therefore to the source 116. The substrate 110 is also doped to form a N+ region 118 within the N-type region 114. The N+ region 118 functions as the drain of the split gate power transistor. A gate contact terminal 140 is coupled to the drain 118. A trench 126 is formed in a top surface of the substrate 110. The trench 126 is filled with field oxide. In some embodiments, the trench 126 is formed using a Shallow Trench Isolation (STI) process, and the field oxide filled trench is referred to as a STI region. In other embodiments, the trench 126 is formed using any conventional semiconductor fabrication technique capable of removing a portion of the substrate to form a thick field oxide region.

A gate oxide 128 is formed on the top surface of the substrate 110. In some embodiments, the gate oxide layer is deposited using conventional semiconductor deposition processes. A polysilicon layer is formed over the gate oxide 128. A slice of the polysilicon layer is then removed, forming two electrically isolated polysilicon portions. In some embodiments, the polysilicon portions are formed using conventional semiconductor deposition and etching processes. A first polysilicon portion forms a polysilicon gate 130. A second polysilicon portion forms a field plate 132. The polysilicon gate 130 and the field plate 132 are physically separated by a gap 134, which corresponds to the removed slice of polysilicon. An insulating oxide 138 covers the polysilicon gate 130 and the field plate 132. As shown in FIG. 2, the gate oxide layer 128 between the polysilicon gate 130 and the substrate 110, and the gate oxide layer 128 between the field plate 132 and the substrate 110 is a thin oxide layer. The field plate 132 is electrically isolated from the polysilicon gate 130 by the gap 134, and the field plate 132 is electrically coupled to the source 116. In many applications, power transistors are laid out having many interdigitated stripes, for example a source stripe, a gate stripe, and a drain stripe. For example, the drain stripe functions as the drain contact terminal 140, and the source stripe functions as the source contact terminal 142. In the split gate power transistor, the gate and the field plate can also be laid out in stripes, separated by the gap. For example, the field plate stripe functions as a field plate contact terminal, schematically illustrated in FIG. 2 as field plate contact terminal 144. In reference to FIG. 2, the stripes are oriented into and out of the plane of the page. If the gate is normally connected at end of its stripe, which can be hundreds of microns long, the field plate similarly extends as a stripe, the end of which is electrically connected to the source stripe by a conductive trace. FIG. 2 conceptually illustrates this point as a conductive trace 146 coupling the field plate contact terminal 144 and the source contact terminal 142. Alternatively, the field plate 132 and the source 116 can be electrically coupled along an entire width of the device, or along periodic contact points along the device width, where the width of the device is into and out of the page of FIG. 2. In these alternative configurations, a gap is cut into the oxide 138 to provide a contact access point to the field plate 132. A gap is cut in the oxide 138 at each desired contact point or region.

The field plate 132 extends over the field oxide filled trench 126 to support high gate-to-drain voltage. The field plate 132 is necessary to maintain the breakdown voltage. If the field plate is removed, for example the entire polysilicon gate portion above the transition region is removed, the breakdown voltage suffers. In this case, almost all the gate-to-drain voltage is dropped across the thin gate oxide, which does not enable the power transistor to meet the rated voltage.

There are three main regions in the substrate 110 relative to the operation of the split gate power transistor: a channel region, a transition region, and a drift region. The channel region is formed underneath the polysilicon gate 130 and in the P-type region 112 of the substrate 110. In other words, the channel region is formed where the polysilicon gate 130 overlaps the P-type region 112. The drift region is the portion of the N-type region 114 underneath the trench 126, or the STI region. The drift region is necessary to support a high gate-to-drain voltage. If the field plate 132 were to instead terminate over the thin gate oxide, this would result in too high a voltage over the gate oxide and the split gate power transistor would not function. As such, the STI region and the field plate extension over the STI region are necessary to drop the high gate-to-drain voltage.

The transition region is the portion of the N-type region 114 underneath the gate oxide 128, the gap 134, and the field plate 132. The transition region provides a current flow path from the channel region to the drift region when the split gate power transistor is turned on. The transition region is also referred to as the accumulation region or the neck region.

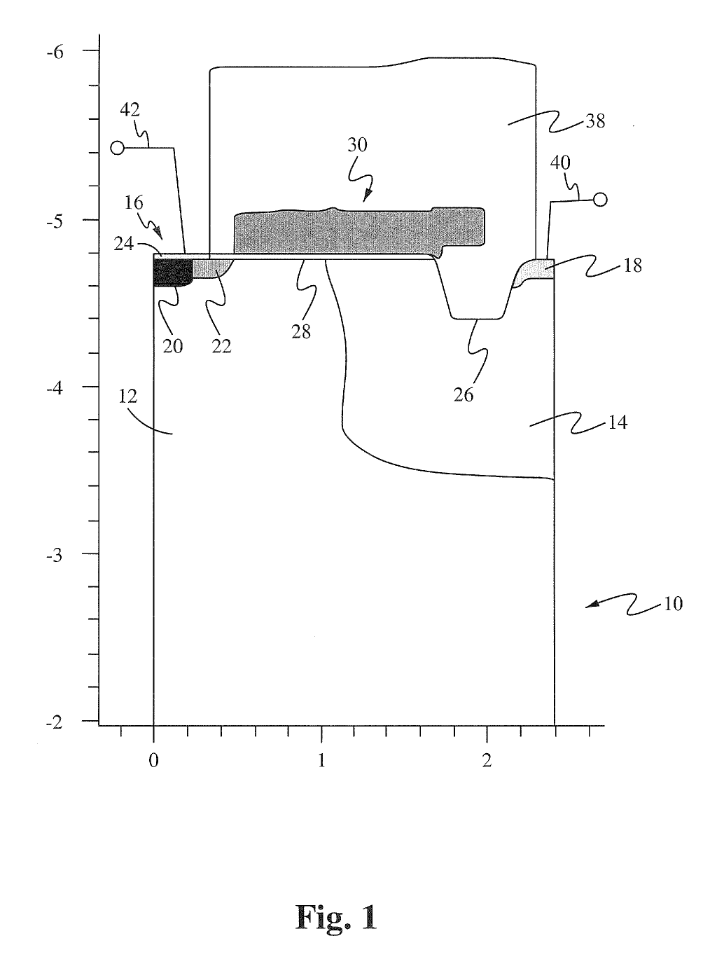

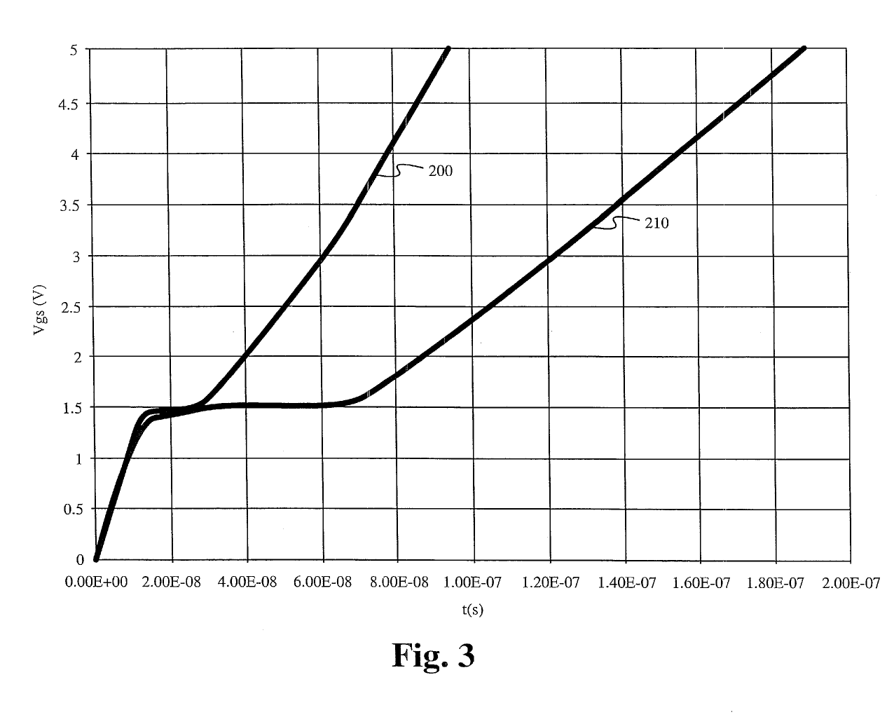

FIG. 3 illustrates a gate charge curve for a conventional power MOSFET, such as that shown in FIG. 1, and the split gate power MOSFET of FIG. 2. The gate charge curve is a common figure of merit for MOSFETs. To determine the gate charge, the drain is connected to a nominal supply voltage through a load resistance, the source is grounded, and the gate is grounded. A constant current is forced into the gate, and the gate-to-source voltage Vgs is measured. As the supply voltage is applied to the gate, the gate-to-source voltage Vgs starts to rise until the threshold voltage is reached, which is 1.5V in this example. The threshold voltage corresponds to the flat portion of the curve, which is where the power transistor begins to turn on. When the gate-to-source voltage Vgs reaches the fully rated voltage, which is 5V in this example, the trace is stopped. The gate charge is determined as the integration of the measured voltage. In the example shown in FIG. 3, the gate charge curves are measured for power MOSFETS having a rated gain-to-source voltage of 5V and an operating voltage of 24V. In general, the operating voltage range is 14V to 60V without having to increase the footprint of the polysilicon that forms the active gate and the field plate of the split gate power transistor.

The curve 200 is the gate charge curve of the split gate power transistor of FIG. 2, and the curve 210 is for a similar conventional power transistor, such as the power transistor of FIG. 1. It is seen in FIG. 3 that the gate charge of the split gate power transistor is reduced by about 50% compared to the conventional power transistor. Reducing the size of the active gate, by removing the slice of polysilicon, reduces the gate charge. It is still necessary to prevent the breakdown of the split gate power transistor, which is accomplished using the field plate. The active polysilicon gate and the field plate are electrically isolated so that the charge that effects the active gate is reduced to the lowest possible level.

It can also be seen that the flat portion of the curve 200 is reduced by approximately 75% compared to the flat portion of the curve 210. The flat portion represents the gate-to-drain charge Qgd, which is the integral of the gate-to-drain voltage across the flat region. Within the flat region, more and more current is forced into the gate, but the gate-to-source voltage remains constant. The gate-to-drain charge Qgd is related to the feedback capacitance between the drain and the gate. In general, the portion of the gate that is positioned over the drain well is amplified and has more of an effect on the gate charge than the portion of the gate that is over the source well. Electrically connecting the field plate to the source, as is done in the split gate power transistor, effectively puts a conductive shield in between the gate and the drain. This reduces the feedback capacitance related to the Miller effect. The reduced flat portion on the gate charge curve reflects this reduction in the feedback capacitance.

The split gate power transistor provides a reduction in the product of on-resistance (R) and gate charge (Qg). An on-resistance of the power MOSFET is the resistance between the drain and the source while the transistor is turned on. However, there is a slight increase in the product of on-resistance (R) and gate area (A), referred to as the specific on-resistance. The specific on-resistance provides a conceptual measure of the size of the power transistor. The specific on-resistance of the split gate configuration rises not due to an increase in the physical gate area A, as the half-pitch of the split gate power transistor having the two polysilicon stripes remains the same as that of the comparable conventional power transistor having a single polysilicon stripe. Instead, the specific on-resistance increases due to an increase in the on-resistance R. When the split gate power transistor is turned completely on, for example when the gate-to-source voltage Vgs=5V, the current flows through the channel region, across the transistor region and the drift region, which is under the field oxide filled trench, and back up to the N+ drain. In the conventional configuration where the polysilicon gate covers the transition region, the polysilicon gate above the transition region is at 5V, which accumulates electrons in the transition region. When the gate-to-source voltage Vgs is positive, the transition region is considered accumulated, not inverted. With more electrons accumulated in the transition region, the resistance is reduced. However, in the split gate configuration, a portion of the polysilicon gate over the transition region is removed, and the remaining portion (the field plate) is connected to the source, not the 5V of the active gate. As such, electrons are not accumulated in the transition region, the transition region simply has its natural equilibrium concentration of electrons. As compared to the non-split gate configuration, there are fewer electrons in the transition region, which results in a higher resistance. In an exemplary application, there is an approximate 44% reduction in the R*Qg product, and an approximate 12% increase in the product R*A.

The split gate power transistor also improves the hot carrier lifetime since the grounded field plate directs on-current away from the gate oxide and increases the breakdown voltage Bvdss. The field plate reduces the electric field for any given supply voltage, which effectively maintains or increases the breakdown voltage of the split gate power transistor. In general, the split gate configuration and field oxide filled trench dissipates excess charge and avoids premature breakdown of the split gate power transistor. The improved hot carrier lifetime and increased breakdown voltage leads to partial recovery of the 12% increase in the R*A product. In the split gate configuration, the field plate extends over the STI region, and the field plate is electrically connected to the source. The resulting source-to-drain capacitance increases by an amount that is slightly less than the reduction in the gate-to-drain capacitance. So the source-to-drain capacitance is higher, but overall there is an efficiency improvement.

In an exemplary application, the cut gap 134 (FIG. 2) between the polysilicon gate 128 and the field plate 132 is fabricated using 0.18 micron semiconductor processing technology, resulting in a 0.25 micron wide gap. However, the gap can be larger or smaller than 0.25 microns, limited in size only by the available technology. For example, utilization of 0.13 micron semiconductor fabrication technology can achieve a gap width of 0.2 microns. In practice, the gap can be as small as technology allows, thereby minimizing the overall size of the transistor, such as the half-pitch. In general, formation of the split gate power transistor is accomplished without increasing the half-pitch, as compared to a comparable power transistor without the split gate configuration.

The following highlight some of the electrical properties of the split gate power transistor, especially as compared to a comparable power transistor. First, the on-resistance is slightly higher (about 12% higher for a 24 V device) because the transition region is no longer accumulated when the device is turned on. The field plate is connected to the source so the field plate is grounded, and the transition region does not have as high a concentration of electrons. Second, the gate capacitance and the gate charge are reduced because of smaller gate area. Third, because the source-connected field plate is positioned between the gate and the drain, the gate-to-drain feedback capacitance is greatly reduced. This further reduces the gate charge because during switching, the gate-to-drain capacitance is amplified by the Miller effect. Fourth, peak impact ionization is reduced so that the hot carrier lifetime is improved. Or, for a given hot carrier lifetime, the half-pitch is reduced. Fifth, the breakdown voltage BVdss increases. Sixth, switch mode power supply (SMPS) efficiency is improved.

Embodiments of the split gate power transistor are described above as N-channel MOSFETs. Alternative embodiments are also contemplated, for example a P-channel MOSFET. Application to a P-channel MOSFET requires a slightly different configuration. Alternative configurations can be implemented where the split gate power transistor is configured with all aspects having opposite polarities than those shown in the described embodiments.

The gate material is described above as being polysilicon. Alternatively, the gate can be made of any conventional material used in the fabrication of semiconductor transistors including, but not limited to, polysilicon and/or metal. The substrate is described above as being silicon. Alternatively, the substrate can be a silicon-based compound, for example silicon germanium (SiGe).

The split gate power transistor has been described in terms of specific embodiments incorporating details to facilitate the understanding of the principles of construction and operation of the power transistor. Such references, herein, to specific embodiments and details thereof are not intended to limit the scope of the claims appended hereto. It will be apparent to those skilled in the art that modifications can be made in the embodiments chosen for illustration without departing from the spirit and scope of the power transistor.

What is claimed is:

1. A power transistor comprising:
a. a doped substrate comprising a source and a channel region within a first doped region, a drain and a transition region within a second doped region, and a trench within the second doped region, wherein the trench is formed in a first surface of the substrate and the trench is filled with field oxide, further wherein the channel region is positioned between the source and the transition region, the transition region is positioned between the channel region and the trench, and the trench is positioned between the transition region and the drain;
b. a gate oxide layer positioned on the first surface of the substrate;
c. a gate positioned on the gate oxide layer and over the channel region; and
d. a field plate positioned on the gate oxide layer and over a first portion of the transition region and a portion of the trench, wherein the gate is separated from the field plate such that a second portion of the transition region is uncovered by both the gate and the field plate, further wherein the field plate is electrically coupled to the drain via a conductive trace.

2. The power transistor of claim 1 wherein the gate and the field plate comprise polysilicon.

3. The power transistor of claim 1 wherein the first doped region is a P-type region and the second doped region is a N-type region.

4. The power transistor of claim 1 wherein the power transistor comprises a lateral double-diffused metal-oxide-semiconductor field-effect transistor.

5. The power transistor of claim 1 wherein the doped substrate further comprises a drift region within the second doped region, wherein the drift region is positioned under the trench.

6. The power transistor of claim 1 further comprising a conductive drain terminal coupled to the drain and a conductive source terminal coupled to the source, wherein the source terminal is coupled to the field plate via the conductive trace.

7. The power transistor of claim 1 wherein the substrate comprises a silicon substrate.

8. The power transistor of claim 1 where the source comprises a double-diffused region.

9. A method of fabricating a power transistor, the method comprising:
a. doping a substrate to form a source and a channel region within a first doped region, a drain and a transition region within a second doped region, wherein the channel region is positioned between the source and the transition region, and the transition region is positioned between the channel region and the drain;
b. forming a trench within a portion of the transition region proximate the drain;
c. filling the trench with a field oxide;
d. applying a gate oxide layer to a top surface of the substrate;
e. forming a conductive layer over the channel region, the transition region, and a portion of the trench;
f. removing a portion of the conductive layer over a first portion of the transition region, thereby forming two separate conductive layer portions including a first conductive layer portion positioned over the channel region, and a second conductive layer portion positioned over a second portion of the transition region and the portion of the trench; and
g. forming a conductive trace to electrically couple the second conductive layer portion to the source.

10. The method of claim 9 further comprising forming a conductive source terminal on the source in the substrate and forming a conductive drain terminal on the drain in the substrate, wherein the source terminal is electrically coupled to the second conductive layer via the conductive trace.

11. The method of claim 9 wherein the gate and the field plate comprise polysilicon.

12. The method of claim 9 wherein the first doped region is a P-type region and the second doped region is a N-type region.

13. The method of claim 9 wherein the power transistor comprises a lateral double-diffused metal-oxide-semiconductor field-effect transistor.

14. The method of claim 9 wherein the doped substrate further comprises a drift region within the second doped region, wherein the drift region is positioned under the trench.

15. The method of claim 9 wherein the substrate comprises a silicon substrate.

16. The method of claim 9 where the source comprises a double-diffused region.

17. The method of claim 9 wherein the trench is formed using a shallow trench isolation process.
